(19) United States
(12) Patent Application Publication
(10) Pub. No.: US 2009/0284941 A1
(43) Pub. Date: Nov. 19, 2009

(54) SEMICONDUCTOR PACKAGE, MOUNTING CIRCUIT BOARD, AND MOUNTING STRUCTURE

(76) Inventor: Kouji OOMORI, Shiga (JP)

Correspondence Address: MCDERMOTT WILL & EMERY LLP, 600 13TH STREET, NW, WASHINGTON, DC, 20005-3096, US

(21) Appl. No.: 12/367,875

(22) Filed: Feb. 9, 2009

(30) Foreign Application Priority Data
May 15, 2008 (JP) 2008-128719

(51) Int. Cl. H05K 1/18; H05K 1/16

(52) U.S. Cl. 361/761; 361/782

(57) ABSTRACT

A semiconductor package includes: a circuit board having a passive component embedded therein; and external terminals provided on a back surface of the circuit board. The passive component is provided at a different position from positions of the external terminals in a thickness direction of the circuit board.

### CROSS-REFERENCE TO RELATED APPLICATIONS

This application claims priority under 35 U.S.C. §119(a) on Japanese Patent Application No. 2008-128719 filed on May 15, 2008, the entire contents of which are hereby incorporated by reference.

### BACKGROUND OF THE INVENTION

The present invention relates to a semiconductor package, a mounting circuit board, and a mounting structure.

With recent reduction in size and improvement in performance of electronic equipments, the pin count, processing speed, and transmission speed of semiconductor elements of the electronic equipments have been increased. In order to normally operate the semiconductor elements, a multilayer board having a multiplicity of passive components has been increasingly used as a printed board on which a package having a semiconductor element is mounted. With increase in the number of components included in the multilayer board, the passive components (typically, a capacitor element) have been required to be embedded in the multilayer board. Power supply noise is generated from the semiconductor elements of the electronic equipments. Forming a capacitor element as close to the semiconductor element as possible has been known as a measure for reducing the power supply noise. It has therefore been proposed to embed the capacitor element in an interposer substrate of a semiconductor package.

The following method has been known as a method for embedding a capacitor in a multilayer board. First, vias are formed in an insulating material, and the insulating material having the vias and wirings (Cu wirings) of a circuit board are laminated to each other. Passive components are then mounted on the Cu wirings, and the insulating material and the Cu wirings are then pressed together. A substrate having the passive components embedded therein is thus formed.

FIG. 6A is a cross-sectional view of a mounting structure of a BGA (ball grid array)-type semiconductor package as a conventional semiconductor package. FIG. 6B is a partial enlarged cross-sectional view of the mounting structure of the semiconductor package shown in FIG. 6A.

In the semiconductor package and the mounting structure thereof shown in FIGS. 6A and 6B, a semiconductor package 1 is formed as follows: a circuit board 2 having a circuit pattern (not shown) and an electrode portion (not shown) formed on both front and back surfaces thereof is prepared. A semiconductor chip 3 is die-bonded to the center of one surface (hereinafter, referred to as the front surface) of the circuit board 2 and then wire-bonded with wires 4. The front surface of the circuit board 2 is then covered by a transfer molding method with a sealing resin 5 for sealing the semiconductor chip 3 and the wires 4. A plurality of electrode terminals 10a are formed on the other surface (hereinafter, referred to as the back surface) of the circuit board 2. The electrode terminals 10a serve as external terminals (ball electrodes) for mounting the semiconductor package 1 on another mounting circuit board.

The circuit board 2 is formed by laminating a glass epoxy insulating material 8a and a copper wiring pattern 7a. Ceramic passive components 9a are embedded in the circuit board 2. Each passive component 9a is connected to the wiring pattern 7a of the circuit board 2 through a via 6a.

The plurality of electrode terminals 10a are arranged in a plurality of lines on the back surface of the circuit board 2. Electrode terminals 10b of a mounting circuit board 12 are solder-connected to the electrode terminals 10a of the circuit board 2, whereby the mounting structure is completed.

Note that the above technology is described in, for example, Japanese Patent No. 3,375,555 (Japanese Patent Laid-Open Publication No. H11-220262), Japanese Patent Laid-Open Publication No H10-097952, and Japanese Patent Laid-Open Publication No. 2002-359160.

### SUMMARY OF THE INVENTION

Such a mounting structure formed by a semiconductor package using a circuit board having passive components embedded therein and a mounting circuit board has the following problem: if a passive component is embedded right above an external terminal provided on the back surface of the circuit board of the semiconductor package or right under an electrode terminal of the mounting circuit board, distortion is generated in the passive component and a solder bonding portion of the mounting structure due to a thermal shock or the like. Such distortion may reduce the strength of the solder bonding portion between the external terminal of the circuit board of the semiconductor package and the electrode terminal of the mounting circuit board.

The same problem occurs in the case where a semiconductor chip is embedded in a circuit board of a semiconductor package. In other words, if a connection portion between a wiring pattern of the circuit board and the semiconductor chip is present right above an external terminal provided on the back surface of the circuit board of the semiconductor package or right under an electrode terminal of a mounting circuit board, distortion is generated in a solder bonding portion of a mounting structure and the bonding portion of the semiconductor chip due to a thermal shock or the like.

According to the present invention, in a semiconductor package including: a circuit board having a passive component embedded therein; and external terminals provided on a back surface of the circuit board, the passive component is provided at a different position from positions of the external terminals in a thickness direction of the circuit board.

As another form of the semiconductor package of the present invention, in a semiconductor package including: a circuit board having a semiconductor chip embedded therein; and external terminals provided on a back surface of the circuit board, the semiconductor chip is connected to a wiring of the circuit board, and a connection portion between the semiconductor chip and the wiring is provided at a different position from positions of the external terminals in a thickness direction of the circuit board.

### BRIEF DESCRIPTION OF THE DRAWINGS

FIG. 1A is a cross-sectional view of a mounting structure of a BGA-type semiconductor package as a semiconductor package according to a preferred embodiment of the present invention, and FIG. 1B is a partial enlarged cross-sectional view of the mounting structure of the semiconductor package shown in FIG. 1A;

FIGS. 2A, 2B, and 2C are cross-sectional views sequentially illustrating the steps of a method for forming the semiconductor package according to the preferred embodiment of the present invention;

FIG. 3 is a partial enlarged cross-sectional view of a mounting structure of a semiconductor package according to another preferred embodiment of the present invention;

FIG. 4 is a partial enlarged cross-sectional view of a mounting structure of a semiconductor package according to still another preferred embodiment of the present invention;

FIG. 5A is a cross-sectional view of a mounting structure of a BGA-type semiconductor package as a semiconductor package according to yet another preferred embodiment of the present invention, and FIG. 5B is a partial enlarged cross-sectional view of the mounting structure of the semiconductor package shown in FIG. 5A; and

FIG. 6A is a cross-sectional view of a mounting structure of a BGA-type semiconductor package as a conventional semiconductor package, and FIG. 6B is a partial enlarged cross-sectional view of the mounting structure of the semiconductor package shown in FIG. 6A.

### DETAILED DESCRIPTION OF THE PREFERRED EMBODIMENTS

Hereinafter, embodiments of the present invention will be described in detail with reference to the accompanying drawings. Note that the present invention is not limited to the embodiments described below.

### First Embodiment

A first embodiment of the present invention will now be described with reference to the drawings.

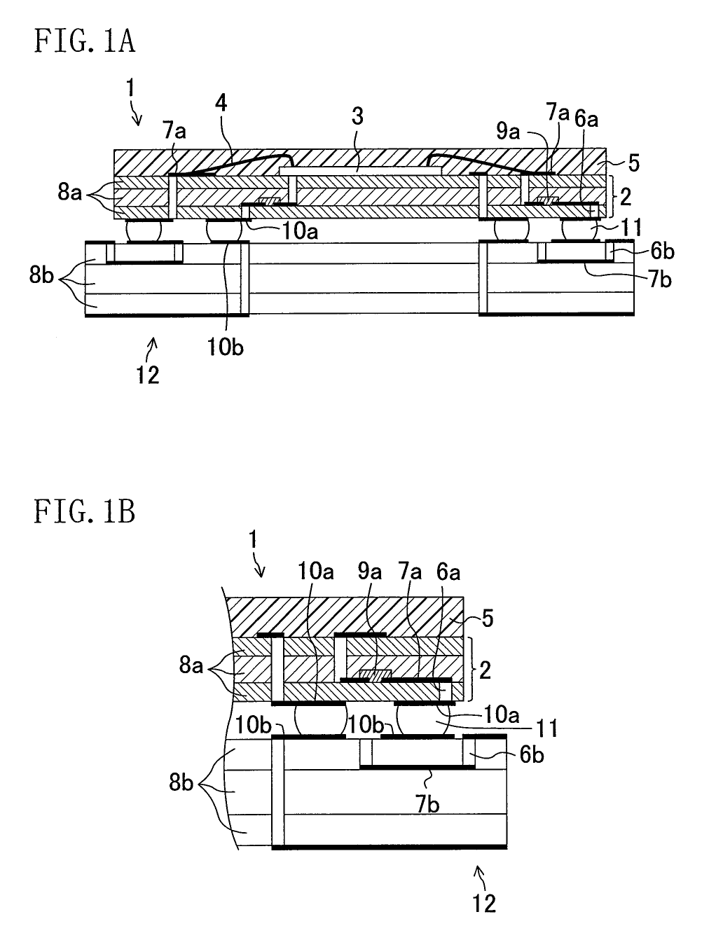

FIG. 1A is a cross-sectional view of a mounting structure of a BGA-type semiconductor package as a semiconductor package according to the first embodiment of the present invention. FIG. 1B is a partial enlarged cross-sectional view of the mounting structure of the semiconductor package shown in FIG. 1A.

A semiconductor package 1 shown in FIGS. 1A and 1B is formed as follows: a circuit board 2 having a circuit pattern (not shown) and an electrode portion (not shown) formed on both front and back surfaces thereof is prepared. A semiconductor chip 3 is die-bonded to the center of one surface (hereinafter, referred to as the front surface) of the circuit board 2 and then wire-bonded with wires 4. The front surface of the circuit board 2 is then covered by a transfer molding method with a sealing resin 5 for sealing the semiconductor chip 3 and the wires 4. A plurality of electrode terminals 10a are formed on the other surface (hereinafter, referred to as the back surface) of the circuit board 2. The electrode terminals 10a serve as external terminals for mounting the semiconductor package 1 on another mounting circuit board.

The circuit board 2 is formed by using a glass epoxy as a base material, and an epoxy resin is used as the sealing resin 5.

The circuit board 2 is a multilayer wiring board formed by laminating a glass epoxy insulating material 8a and a copper wiring pattern (wirings) 7a. Ceramic passive components 9a are embedded in the circuit board 2. Each passive component 9a is connected to the wiring pattern 7a of the circuit board 2 through a via 6a.

The plurality of electrode terminals 10a are arranged in a plurality of lines on the back surface of the circuit board 2. Electrode terminals 10b of a mounting circuit board 12 are arranged at the same positions as those of the electrode terminals 10a. The electrode terminals 10b are connected to the electrode terminals 10a of the circuit board 2 through solder bonding portions 11 (ball electrodes).

Each passive component 9a embedded in the circuit board 2 is provided at a different position from the positions of the electrode terminals 10a in the thickness direction of the circuit board 2.

Nickel plating of about 5 μm thickness and gold plating of about 0.1 μm to about 1.0 μm thickness are provided on the surface of the electrode terminals 10a. The solder bonding portions 11 are made of a lead-free solder material containing tin, silver, and copper as main components.

Like the circuit board 2, the mounting circuit board 12 is also a multilayer wiring board formed by laminating a glass epoxy insulating material 8b and a copper wiring pattern (wirings) 7b. Vias 6b are formed so as to extend through the insulating material 8b. The electrode terminals 10b formed on the top surface of the mounting circuit board 12 are electrically connected to a conductive material provided in the vias 6b.

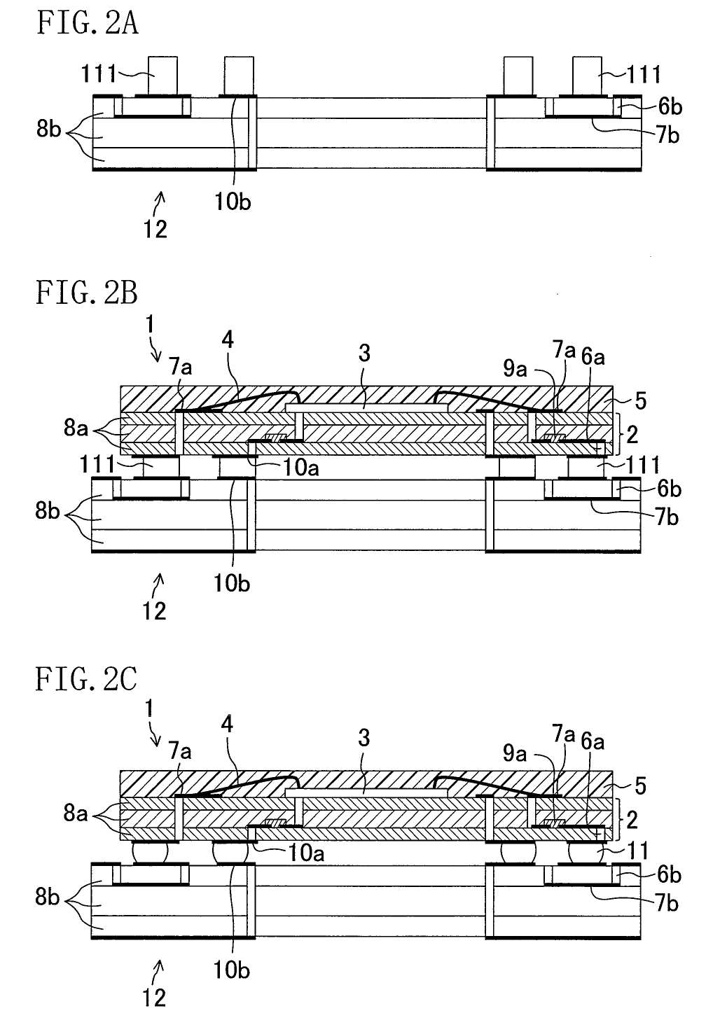

A method for bonding the semiconductor package 1 and the mounting circuit board 12 by the solder bonding portions 11 will now be described with reference to FIGS. 2A through 2C.

As shown in FIG. 2A, a solder paste 111 is printed on the electrode terminals 10b of the mounting circuit substrate 12. As shown in FIG. 2B, the semiconductor package 1 is then mounted and the solder paste 111 is melted by heating in a reflow furnace (not shown) to form an alloy at the interface between the solder and the electrode terminals 10a of the circuit board 2. The electrode terminals 10a of the circuit board 2 and the electrode terminals 10b of the mounting circuit board 12 are thus bonded together. A mounting structure shown in FIG. 2C can thus be completed.

In the case of using the mounting structure of this form, distortion is generated by a thermal shock due to the difference in thermal expansion among the sealing resin 5, the circuit board 2, and the mounting circuit board 12. As a result, a stress is applied to the solder bonding portions 11 of the mounting structure. In the present embodiment, however, each passive component 9a embedded in the circuit board 2 is provided at a different position from the positions of the solder bonding portions 11 in the thickness direction of the circuit board 2. In other words, each passive component 9a is provided at a different position from the positions of the electrode terminals 10a of the circuit board 2 in the thickness direction of the circuit board 2. This prevents distortion of the passive component 9a and the circuit board 2 from being directly applied to the solder bonding portions 11, thereby providing the effect of suppressing degradation in mounting reliability. Especially, the largest stress is applied to the bonding portions in the four corners of the semiconductor package 1. It is therefore desirable not to provide the passive component 9a right above the solder bonding portions 11 in the four corners of the semiconductor package 1. Moreover, the largest stress is also applied to the bonding portions in the four corners of the semiconductor package due to an impact upon dropping or the like. The mounting structure of the present embodiment is therefore effective.

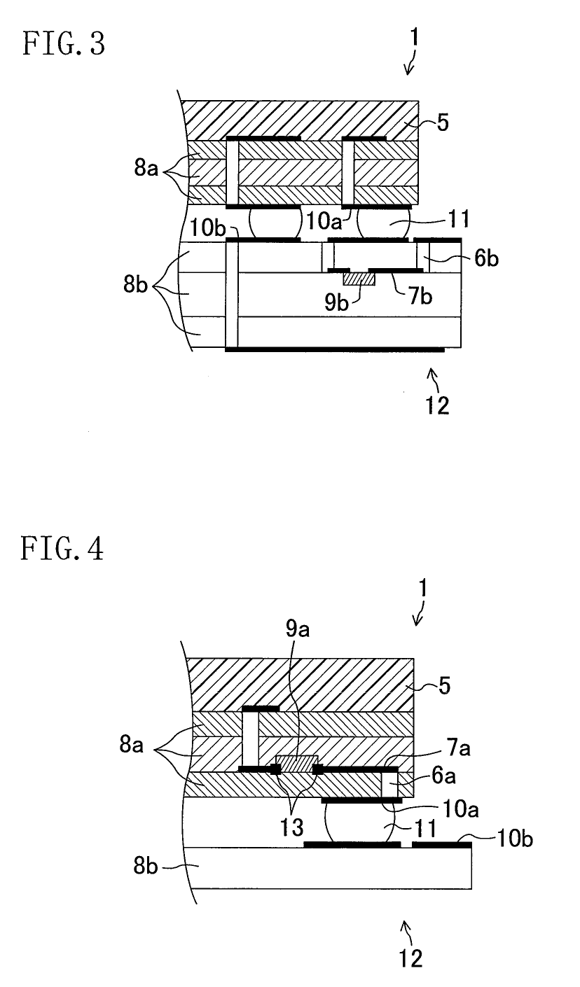

In the case where a passive component 9b is embedded in the mounting circuit substrate 12 as shown in FIG. 3, the same effect as described above can be obtained by providing the passive component 9b at a different position from the positions of the electrode terminals 10b of the mounting circuit board 12 in the thickness direction of the mounting circuit board 12.

In the case where the connection portion between the passive component 9a embedded in the circuit board 2 and the wiring pattern 7a is present right above the solder bonding portions 11 in the mounting structure of the semiconductor package 1, that is, in the case where the connection portion between the wiring pattern 7a of an inner layer of the circuit board 2 and the passive component 9a is present right above the electrode terminals 10a of the circuit board 2, a stress is applied to the connection portion between the passive component 9a and the wiring pattern 7a due to distortion of the solder bonding portions 11 and the circuit board 2. Reliability of the connection portion is therefore degraded.

As shown in FIG. 4, however, in the case where a connection portion 13 between the passive component 9a and the wiring pattern 7a is provided at a different position from the positions of the electrode terminals 10a of the circuit board 2 in the thickness direction of the circuit board 2, degradation in reliability of the connection portion 13 between the passive component 9a and the wiring pattern 7a can be suppressed.

In the present embodiment, an insulating resin that is used as an insulating material of a portion other than an insulating material made of a high dielectric constant material is not specifically limited. However, it is preferable to use an insulating resin other than a high dielectric constant material. It is more preferable to use an insulating resin reinforced by a glass base material and having an inorganic filler added thereto.

Preferably, the passive component includes at least one component selected from a chip-like resistor element, a chip-like capacitor element, and a chip-like inductor element. The use of a chip-like component enables the passive component to be easily embedded in the circuit board.

Preferably, the semiconductor chip is a semiconductor bare chip and is flip-chip bonded to the wiring pattern. Flip-chip bonding the semiconductor bare chip enables high-density mounting of semiconductor elements on the mounting circuit board.

### Second Embodiment

A second embodiment of the present invention will now be described with reference to the drawings.

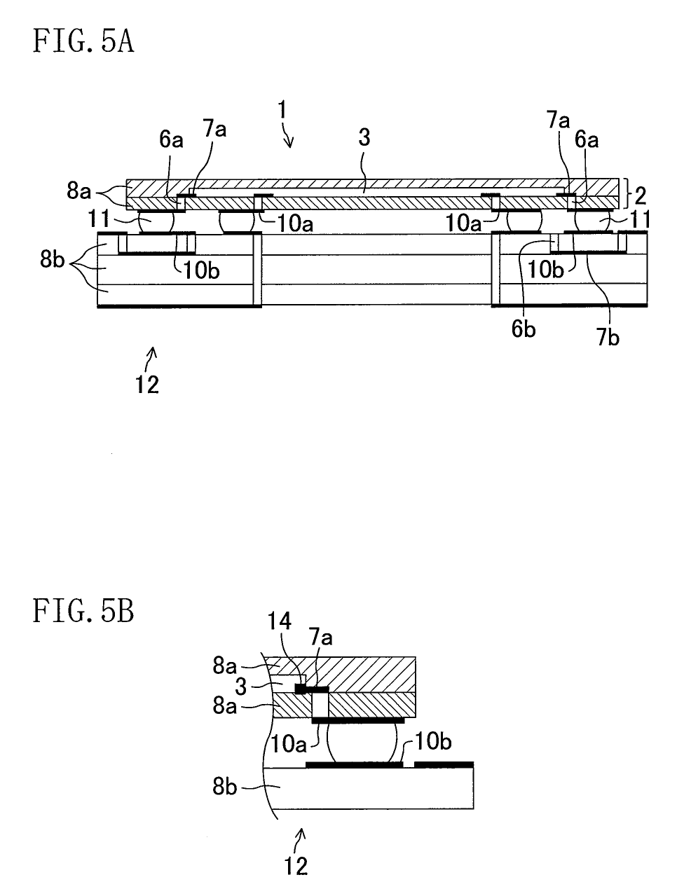

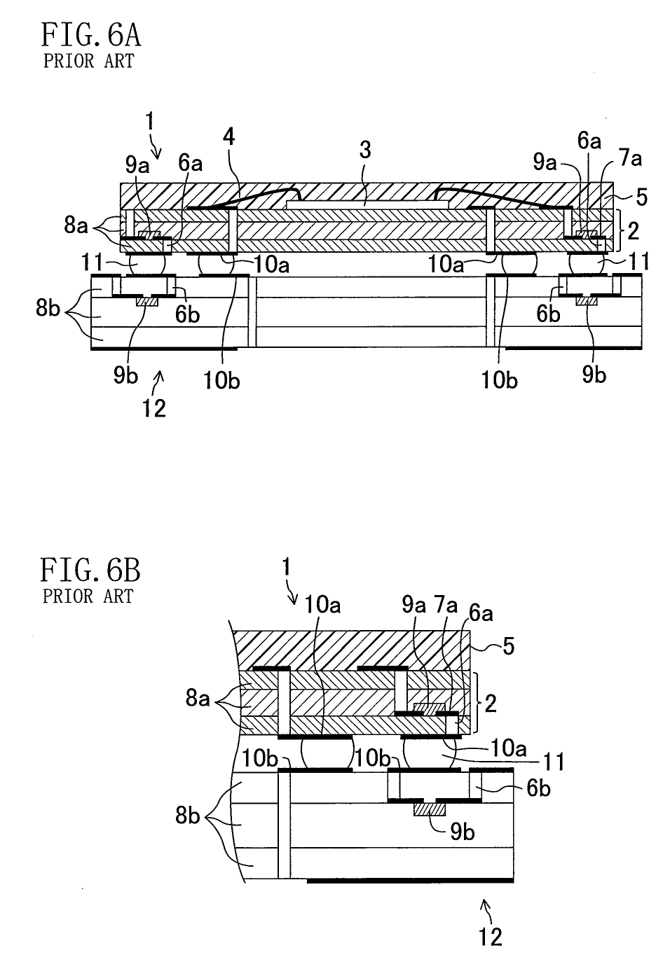

FIG. 5A is a cross-sectional view of a mounting structure of a semiconductor package according to the second embodiment of the present invention. FIG. 5B is a partial enlarged cross-sectional view of the mounting structure of the semiconductor package shown in FIG. 5A.

In the mounting structure of the semiconductor package shown in FIGS. 5A and 5B, a circuit board 2 is formed by laminating a glass epoxy insulating material 8a and a copper wiring pattern 7a, and a semiconductor chip 3 is embedded in the circuit board 2. The semiconductor chip 3 is connected to the wiring pattern 7a of the circuit board 2 through vias 6a.

A plurality of electrode terminals 10a are formed on one surface (hereinafter, referred to as the back surface) of the circuit board 2. Each electrode terminal 10a serves as an external terminal for mounting the semiconductor package 1 to a mounting circuit board (mount board). A solder bonding portion (ball electrode) 11 is bonded on each electrode terminal 10a.

The plurality of electrode terminals 10a are arranged in a plurality of lines on the back surface of the circuit board 2. Electrode terminals 10b of a mounting circuit board 12 are connected to the electrode terminals 10a through solder bonding portions 11.

In the present embodiment, a connection portion 14 between the semiconductor chip 3 embedded in the circuit board 2 and the wiring pattern 7a and an end of the semiconductor chip 3 are provided at different positions from the positions of the electrode terminals 10a in the thickness direction of the circuit board 2.

In the case where a mounting structure is formed by mounting the semiconductor package 1 on the mounting circuit board 12 with the solder bonding portions 11 and the connection portion between the semiconductor chip 3 and the wiring pattern 7a is located right above the solder bonding portions 11, that is, right above the electrode terminals 10a, a stress is applied to the connection portion between the semiconductor chip 3 and the wiring pattern 7a and the solder bonding portions 11 due to distortion of the solder bonding portions 11 and the circuit board 2. Reliability of the connection portion is therefore degraded. Accordingly, it is desirable to provide the connection portion 14 between the semiconductor chip 3 and the wiring pattern 7a at a different position from the positions of the electrode terminals 10a in the thickness direction of the circuit board 2, as in the present embodiment.

What is claimed is:

1. A semiconductor package, comprising: a circuit board having a passive component embedded therein; and external terminals provided on a back surface of the circuit board, wherein the passive component is provided at a different position from positions of the external terminals in a thickness direction of the circuit board.

2. The semiconductor package according to claim 1, wherein the passive component is made of a ceramic material.

3. The semiconductor package according to claim 1, wherein the circuit board has a semiconductor chip embedded therein, the semiconductor chip is connected to a wiring of the circuit board, and a connection portion between the semiconductor chip and the wiring is provided at a different position from the positions of the external terminals in the thickness direction of the circuit board.

4. A semiconductor package, comprising: a circuit board having a semiconductor chip embedded therein; and external terminals provided on a back surface of the circuit board, wherein the semiconductor chip is connected to a wiring of the circuit board, and a connection portion between the semiconductor chip and the wiring is provided at a different position from positions of the external terminals in a thickness direction of the circuit board.

5. A mounting circuit board, comprising electrode terminals respectively connected to external terminals provided in a semiconductor package, wherein the mounting circuit board has a passive component embedded therein, and the passive component is provided at a different position from positions of the electrode terminals in a thickness direction of the mounting circuit board.

6. The mounting circuit board according to claim 5, wherein the passive component is made of a ceramic material.

7. The mounting circuit board according to claim 5, wherein the mounting circuit board has a semiconductor chip embedded therein, the semiconductor chip is connected to a wiring of the mounting circuit board, and a connection portion between the semiconductor chip and the wiring is provided at a different position from the positions of the electrode terminals in the thickness direction of the mounting circuit board.

8. A mounting circuit board, comprising electrode terminals respectively connected to external terminals provided in a semiconductor package, wherein the mounting circuit board has a semiconductor chip embedded therein, the semiconductor chip is connected to a wiring of the mounting circuit board, and a connection portion between the semiconductor chip and the wiring is provided at a different position from positions of the electrode terminals in a thickness direction of the mounting circuit board.

9. A mounting structure having a semiconductor package solder-connected to a mounting circuit board, wherein the semiconductor package is the semiconductor package according to claim 1 or 4.

10. A mounting structure having a semiconductor package solder-connected to a mounting circuit board, wherein the mounting circuit board is the mounting circuit board according to claim 5 or 8.

11. The mounting structure according to claim 9, wherein the mounting circuit board is the mounting circuit board according to claim 5 or 8.
